(19) United States
(12) Patent Application Publication
(10) Pub. No.: US 2025/0140300 A1
(43) Pub. Date: May 1, 2025

(54) Traffic Aware Adaptive Precharge Scheduler For Efficient Refresh Management In Dram Memory Controllers

(71) Applicant: Google LLC, Mountain View, CA (US)

(72) Inventors: Nagaraj Ashok Putti, Cupertino, CA (US); Venkateswaran Ananthanarayanan, Karnataka (IN); Preethi Ashok Kumar, Karnataka (IN); Praxal Sunilkumar Shah, Atlanta, GA (US); Jaskirat Singh, Karnataka (IN)

(21) Appl. No.: 18/835,381

(22) PCT Filed: Feb. 4, 2022
(86) PCT No.: PCT/US2022/015284

§ 371 Date: Aug. 2, 2024

(51) Int. Cl. G11C 11/406

(52) U.S. Cl. CPC G11C 11/40603; G11C 11/40615; G11C 11/40618

(57) ABSTRACT

This specification describes memory controllers with adaptive precharge scheduling. In one aspect, a memory controller includes a refresh scheduler configured to send refresh commands to dynamic random-access memory (DRAM) banks of a DRAM memory system that includes DRAM banks arranged in a set of DRAM bank groups each comprising one or more DRAM banks. The memory controller includes an adaptive precharge scheduler configured to determine a priority score for each DRAM bank group based on a set of parameters, select, based on the priority score for each DRAM bank group, a particular DRAM bank group to close so that each DRAM bank in the DRAM bank group can be refreshed by the refresh scheduler, and send the precharge command to at least one DRAM bank of the particular DRAM group.

### TECHNICAL FIELD

This specification relates to dynamic random-access memory (DRAM) memory controllers.

### BACKGROUND

A DRAM cell is a memory cell that typically includes an access transistor and a capacitor for storing a bit of data. The capacitor can either be charged or discharged to represent the two values of a bit, zero or one. The capacitor tends to leak its stored charge over time. Thus, without intervention, the data stored in DRAM would be lost. To prevent this data loss, the data stored in DRAM is refreshed periodically, e.g., using refresh commands issued by a DRAM memory controller. Each DRAM cell must be refreshed periodically based on the DRAM standards, e.g., the JEDEC memory standards. Refreshing a DRAM cell typically includes reading and rewriting the data to the DRAM cell, which restores the capacitor to its previous charge.

The refresh process negatively affects the performance and power usage/dissipation of the DRAM cells. For example, the DRAM cells of a DRAM bank are stalled during the refresh process, preventing data from being read from or written to the DRAM bank. The refresh process also increases the amount of power used and dissipated by the memory systems due to the reading and rewriting of data to the DRAM cells.

### SUMMARY

This specification relates to dynamic random-access memory (DRAM) memory controllers. A memory controller can include a refresh scheduler that schedules refreshes to DRAM banks, e.g., on a per-bank basis and/or for all banks managed by the memory controller. A refresh scheduler typically issues refresh per bank commands (REFpb) commands to DRAM banks that are closed unless the refresh interval for the DRAM system is closed to lapsing. In so, the refresh scheduler can issue a refresh all banks command (REFab) command to refresh all of the DRAM banks. This causes all banks within the DRAM system to be unavailable until all of the DRAM banks are refreshed.

While REFpb involves targeted refreshing of a bank or a bank pair and allows traffic to continue onto other banks, REFab requires traffic to be stalled to all banks and all banks to be in idle state before the start of REFab command. It is also to be noted that one REFab can be equivalent to issuing 8 REFpb commands and has the same effect.

When memory traffic is ongoing, it is desirable to issue more REFpb commands than REFab commands as it aids system performance by avoiding blackout periods for the DRAM system. The JEDEC standards provide flexibility in choosing the order in which bank pairs are selected while issuing the REFpb command for each cycle and the order can be different for each cycle. Each cycle is defined as one iteration across all the banks within refresh (tREFI) window: A memory controller can typically only issue REFpb to a bank pair only once during the cycle and the memory controller has to finish iterating through all bank pairs before starting another cycle. This enables the memory controller to implement schemes that could potentially result in better system performance by choosing an improved or optimal order of DRAM banks to refresh in each cycle.

As described in this document, a memory controller can include an adaptive precharge scheduler that monitors traffic and intelligently inserts precharges within the traffic stream with an aim to aid the refresh scheduler schedule the refresh per bank commands in a sequence that is least disruptive to the quality of service of the DRAM system. A precharge (PRE) command can close a row of DRAM cells within a DRAM bank such that the refresh scheduler can issue a REFpb command to the DRAM bank.

The adaptive precharge scheduler can interface with transaction buffers (to determine traffic conditions), obtain information of page status of each DRAM bank, get information on impending refresh requirements (are we in prepone stage or postpone stage or close to the tREFi deadline, etc) and weaves all this data into a decision logic that generates the precharge (PRE) commands on the main data interface. Refresh scheduler upon seeing a bank pair being idle proceeds to refresh that bank pair and the adaptive precharge scheduler and the refresh scheduler will be able to complete one full refresh cycle using REFpb commands more often than not and thus avoiding the REFab blackout that would happen otherwise.

By adding adaptive precharge intelligence, a single interface handles the scheduling of both normal traffic as well as precharges (PREs) that aid per bank refreshes. This guards the system from conflicting decisions that could have originated if the refresh scheduler independently scheduled precharges without considering current traffic based decisions made by the request scheduler.

The adaptive precharge scheduler can identify the status (open/close) of each DRAM bank at all times. It is desirable to choose an already closed bank pair to refresh if all other things are equal. Thus, a single DRAM bank (out of a bank pair with one bank already in closed state) can be closed preemptively considering traffic conditions to that bank pair to aid issuing of refreshes to that bank pair.

The adaptive precharge scheduler also tracks the number of transactions that have priority bits set for each DRAM bank. All things being equal, it is desirable to avoid sending refresh commands to banks which have priority transactions. This avoids precharging the bank pairs that have priority requests and instead results in selecting a different bank and directing the refresh scheduler to issue a refresh command (e.g., REFpb) to a different bank pair.

The adaptive precharge scheduler also ensures that an activate to the bank pair does not go through during the time period in which it has selectively precharged a bank or bank pair and made it ready for the refresh scheduler to issue a refresh command (e.g., REFpb) to this bank pair. The memory controller can include a custom interface that enables this communication between the adaptive precharge scheduler and the refresh scheduler.

In general, one innovative aspect of the subject matter described in this specification can be embodied in memory controllers that include a refresh scheduler configured to send refresh commands to dynamic random-access memory (DRAM) banks of a DRAM memory system that include DRAM banks arranged in a set of DRAM bank groups each including one or more DRAM banks. The memory controllers include an adaptive precharge scheduler configured to determine a priority score for each DRAM bank group based on a set of parameters including at least one of (i) one or more status parameters that indicate a status of the one or more DRAM banks or (ii) one or more traffic condition parameters that indicate a characteristic of data traffic for the one or more DRAM bank: select, based on the priority score for each DRAM bank group, a particular DRAM bank group to close so that each DRAM bank in the DRAM bank group can be refreshed by the refresh scheduler; and send the precharge command to at least one DRAM bank of the particular DRAM group. Other implementations of this aspect include corresponding methods, apparatus, and systems.

These and other implementations can each optionally include one or more of the following features. In some aspects, the refresh scheduler is configured to detect that the at least one DRAM bank is closed and send a refresh command to the at least one DRAM bank in response to detecting that the at least one DRAM bank is closed. In some aspects, detecting that the at least one DRAM bank is closed includes receiving, from the adaptive precharge scheduler, data indicating that the at least one DRAM bank is closed.

In some aspects, the one or more status parameters for each DRAM bank group include a parameter indicating a number of DRAM banks of the DRAM bank group that are open. The one or more traffic condition parameters for each DRAM bank group can include a number of memory requests received for the DRAM bank group. The one or more traffic condition parameters for each DRAM bank group can include a number of priority memory requests received for the DRAM bank group. The one or more traffic condition parameters for each DRAM bank group can include a number of memory request conflicts detected for the DRAM bank group. The one or more traffic condition parameters for each DRAM bank group can include a number of priority memory request conflicts detected for the DRAM bank group.

In some aspects, the priority score for each DRAM bank group is represented by a score vector that orders the set of parameters within the score vector based on a relative importance of each parameter. In some aspects, the one or more status parameters for each DRAM bank group comprise a refresh status indicating whether the DRAM bank is in a prepone stage, a postpone stage, or is close to a refresh deadline for the DRAM bank.

Another innovative aspect of the subject matter described in this specification can be embodied in methods that include sending, by a refresh scheduler of a memory controller, refresh commands to dynamic random-access memory (DRAM) banks of a DRAM memory system including DRAM banks arranged in a set of DRAM bank groups each including one or more DRAM banks: determining, by an adaptive precharge scheduler of the memory controller, a priority score for each DRAM bank group based on a set of parameters including at least one of (i) one or more status parameters that indicate a status of the one or more DRAM banks or (ii) one or more traffic condition parameters that indicate a characteristic of data traffic for the one or more DRAM bank: selecting, by the adaptive precharge scheduler and based on the priority score for each DRAM bank group, a particular DRAM bank group to close so that each DRAM bank in the DRAM bank group can be refreshed by the refresh scheduler; and sending, by the adaptive precharge scheduler, the precharge command to at least one DRAM bank of the particular DRAM group. Other implementations of this aspect include corresponding apparatus, systems, and computer programs, configured to perform the aspects of the methods, encoded on computer storage devices.

These and other implementations can each optionally include one or more of the following features. Some aspects can include detecting, by the refresh scheduler, that the at least one DRAM bank is closed and sending a refresh command to the at least one DRAM bank in response to detecting that the at least one DRAM bank is closed. In some aspects, detecting that the at least one DRAM bank is closed includes receiving, from the adaptive precharge scheduler, data indicating that the at least one DRAM bank is closed.

In some aspects, the one or more status parameters for each DRAM bank group comprise a parameter indicating a number of DRAM banks of the DRAM bank group that are open. In some aspects, the one or more traffic condition parameters for each DRAM bank group comprise a number of memory requests received for the DRAM bank group. The one or more traffic condition parameters for each DRAM bank group can include a number of priority memory requests received for the DRAM bank group. The one or more traffic condition parameters for each DRAM bank group can include a number of memory request conflicts detected for the DRAM bank group. The one or more traffic condition parameters for each DRAM bank group can include a number of priority memory request conflicts detected for the DRAM bank group.

In some aspects, the priority score for each DRAM bank group is represented by a score vector that orders the set of parameters within the score vector based on a relative importance of each parameter. In some aspects, the one or more status parameters for each DRAM bank group include a refresh status indicating whether the DRAM bank is in a prepone stage, a postpone stage, or is close to a refresh deadline for the DRAM bank.

The subject matter described in this specification can be implemented in particular embodiments so as to realize one or more of the following advantages. A memory controller can include an adaptive precharge scheduler that obtains information about DRAM banks and uses the information to intelligently issue PRE commands to aid in REFpb refreshes which, in turn, reduces the number of REFab commands that stall traffic to all DRAM banks of a DRAM system. This increases the performance, including the bandwidth efficiency, of the DRAM system by reducing the percentage of time the DRAM banks are inaccessible due to refreshes. This also significantly reduces the latency in accessing data stored in the DRAM that would otherwise occur during all bank refreshes, which increases the performance of applications and/or hardware comments that use the data. Using a single interface to handle both normal memory traffic and precharges that aid per bank refreshes prevents conflicting decisions that could have otherwise originated if the refresh scheduler independently schedules precharges without considering current traffic-based decisions made by the request scheduler. For example, this prevents a request scheduler from opening a row of a DRAM bank to access data when the adaptive precharge scheduler has just closed the DRAM bank to refresh the bank. Preventing this conflicting action increases the likelihood that each DRAM bank can be refreshed each refresh cycle without requiring an all bank refresh.

Various features and advantages of the foregoing subject matter are described below with respect to the figures. Additional features and advantages are apparent from the subject matter described herein and the claims.

### BRIEF DESCRIPTION OF THE DRAWINGS

FIG. 1A shows an example memory system in which a memory controller controls access to DRAM and refreshes DRAM cells of the DRAM.

FIG. 1B shows the example DRAM of FIG. 1A.

FIG. 2 is a flow diagram of an example process for refreshing DRAM cells.

FIG. 3 is a graph that shows bandwidth efficiency improvements of using a traffic aware adaptive precharge scheduler.

Like reference numbers and designations in the various drawings indicate like elements.

### DETAILED DESCRIPTION

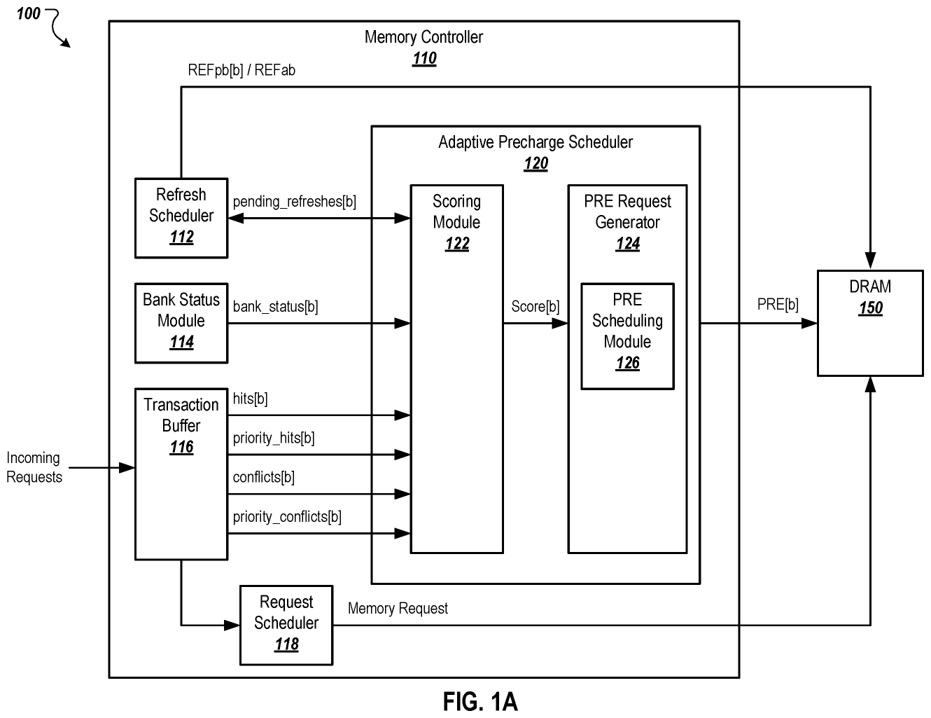

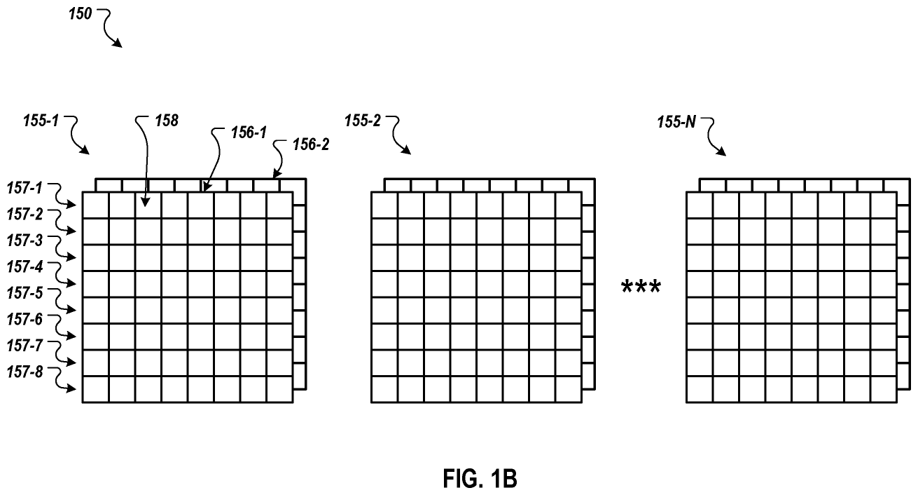

FIG. 1A shows an example memory system 100 in which a memory controller 110 controls access to DRAM 150 and refreshes DRAM cells of the DRAM 150. The DRAM can include multiple DRAM banks that each include one or more rows of DRAM cells. Each row can include multiple DRAM cells. A DRAM cell typically includes an access transistor and a capacitor for storing a value of a bit of data, e.g., a value of one if charged or a value of zero if discharged. The DRAM 150 can be implemented as low power double data rate (LPDDR) DRAM or other appropriate types of DRAM. Although the example memory system 100 includes DRAM, the memory system 100 and its components and functionality can be implemented for other types of memories that require refreshing.

Each DRAM bank can be arranged as a two-dimensional array of DRAM cells having multiple rows and columns. A DRAM row can also be referred to as a DRAM page. The DRAM banks can be arranged in groups that are refreshed together as a group. For example, the DRAM banks can be arranged as bank pairs that each include two DRAM banks.

Referring to FIG. 1B, the example DRAM 150 includes a number “N” DRAM bank pairs 155-1 to 155-N. Each DRAM bank pair 155 includes two DRAM banks 156-1 and 156-2 that each include DRAM cells 156 arranged in eight rows 157-1 to 157-8 and eight columns. In other examples, the DRAM 150 can include DRAM groups that each have a single DRAM bank or more than two DRAM banks, and/or each DRAM bank can include a different number of rows and/or a different number of columns. For example, another DRAM system can have DRAM bank pairs with 16×16 DRAM banks, 32×32 DRAM banks, or other appropriately sized DRAM bank.

Referring back to FIG. 1A, the memory controller 110 includes a refresh scheduler 112, a bank status module 114, a transaction buffer 116, a request scheduler 118, and an adaptive precharge scheduler 120. Of course, the memory controller 110 and the memory system 100 can include additional components that are not shown in FIG. 1, such as decoders, address buffers, registers, etc.

The transaction buffer 116 receives incoming requests to read data from and write data to the DRAM 150 and temporarily stores the requests. For example, the requests can be received from a central processing unit (CPU), a graphics processing unit (GPU), or another type of processor or component, e.g., over a memory bus or other interface that connects the processor or component to the memory system 100.

An incoming request can have a corresponding priority level, e.g., that is provided with the request. For example, a processor can send, to the memory controller 110, requests that include a command to read from or write data to DRAM 150 and a priority level corresponding to the request. The priority level can be represented by a number within a numerical range, e.g., zero to ten or another appropriate range, or as a particular level, e.g., low, moderate, or high. In another example, the processor can label some requests as priority requests and either label non-priority requests as low priority requests or not include a label for non-priority requests.

The request scheduler 118 monitors the transaction buffer 116 for incoming requests that are buffered at the transaction buffer 116. The request scheduler 118 also generates and sends requests to access, e.g., read data from and write data to, DRAM cells of the DRAM 150. In some DRAM systems, an access to DRAM 150 typically includes a sequence of an activate (ACT) command to open a row of a DRAM bank, a column COL read or write command to perform the read/write operation on a subset of the DRAM cells within the row, and a precharge (PRE) command to close the row. Once a row is open, the row can be accessed multiple times through a series of COL commands. Once closed using the PRE command, the row can be opened again using the ACT command to access the row again.

The bank status module 114 can maintain the status of each DRAM bank and/or row of each bank. As described above, the DRAM banks can be arranged as bank pairs. The status of a bank pair can indicate whether one of the DRAM banks of the bank pair is open. For example, the status can be a bit having a first value, e.g., one, when one DRAM bank is open, and second value, e.g., zero, when either both DRAM banks are open or both DRAM banks are closed. In another example, the status can indicate the number of banks open, e.g., zero, one, or two.

The bank status module 114 can be updated by the request scheduler 118. For example, the request scheduler 118 can forward requests to the bank status module 114 and the bank status module 114 can update the status of a DRAM bank, bank pair, or row based on the request. For example, if the request is an ACT command for a row, the bank status module 114 can update the status of the row and the DRAM bank in which the row is included to a status of “open.” The bank status module 114 can determine the number of DRAM banks open in the bank pair that includes the now open DRAM bank and row and update the status of the bank pair based on the determined number. The status information for DRAM bank “b” is represented as “bank_status [b].”

The refresh scheduler 112 schedules refreshes and issues refresh commands, e.g., REFpb and REFab, to the DRAM banks of the DRAM 150. As described above, a REFpb command is a command to refresh a particular DRAM bank “b” or pair of banks and a REFab is a command to refresh all banks of DRAM 150 in the memory system 100. In general, the refresh scheduler 112 issues REFpb commands to DRAM banks that are closed during the refresh interval for the DRAM 150 to prevent or delay having to issue a REFab command to refresh all banks. When issuing REFpb commands to pairs of banks, the refresh scheduler 112 can issue REFpb commands to pairs of banks for which both banks are closed.

The refresh scheduler 112 can be configured to identify, based on the status of the DRAM banks, DRAM banks that are closed and issue REFpb commands to the closed banks during the refresh interval. If the refresh scheduler 112 successfully refreshes all banks of the DRAM 150 using REFpb commands during the refresh interval, the refresh scheduler 112 can avoid having to issue a REFab command to the DRAM for that refresh interval and can move to the next refresh interval. As open banks may be in the process of being accessed, the refresh scheduler 112 may not issue refresh commands to those banks.

The adaptive precharge scheduler 120 can close DRAM banks, e.g. proactively, so that the refresh scheduler 112 can refresh the DRAM banks using REFpb commands. In some implementations, the adaptive precharge scheduler 120 can close a DRAM bank, or bank pair, of the DRAM 150 by issuing a PRE command to the bank or bank pair, or to each open row of the bank or bank pair. Once closed, the refresh scheduler 112 can issue a REFpb command to the DRAM bank or bank pair.

The adaptive precharge scheduler 120 and refresher scheduler 112 can communicate over an interface, e.g., a custom interface that can be implemented using conductors of a chip that includes the memory controller. The adaptive precharge scheduler 120 can use the interface to notify the refresh scheduler 112 when it closes a DRAM bank or bank pair. In another example, the adaptive precharge scheduler 120 can update the status of the banks at the bank status module 114. In this example, the refresh scheduler 112 can detect that a DRAM bank or bank pair is closed (or that the DRAM bank or bank pair recently closed) and issue a REFpb command to the DRAM bank or bank pair.

The adaptive precharge scheduler 120 can issue and/or schedule PRE commands to DRAM banks or banks pairs based on priority scores for the banks or bank pairs. The adaptive precharge scheduler 120 includes a scoring module 122 that determines the priority scores and a PRE request generator 124 that selects DRAM banks for precharges and sends the PRE commands to the DRAM banks.

The scoring module 122 can determine the priority score for a DRAM bank or bank pair based on, for example, traffic conditions for the DRAM banks or bank pairs. For ease of subsequent description, the priority scores are described with reference to bank pairs, but the same or similar scoring can be used for single DRAM banks or groups of DRAM banks that include more than two DRAM banks.

The adaptive precharge scheduler 120 can interface, e.g., using a data communication interface implemented using one or more conductors, with the transaction buffer 116 to obtain information related to status of bank pairs and the traffic conditions of the bank pairs, and generate parameters for the bank pairs. The scoring module 122 can determine the priority scores for the bank pairs based on the parameters related to the status and/or traffic conditions.

One example parameter that can be used to determine a priority score for a bank pair is the number of requests that have been received by the memory controller 110 for the DRAM banks of a bank pair. The adaptive precharge scheduler 120 can monitor the requests received by the transaction buffer 116 to determine the number of requests received to access the bank pair, e.g., over a particular time period. The time period can be a running time period, e.g., the previous second, the previous 10 seconds, the previous minute, or another appropriate time period. The number of requests received over a time period is a traffic condition that indicates the level of activity of the DRAM banks in the bank pair. The adaptive precharge scheduler 120 can determine the number of requests for a DRAM bank by maintaining a count of the number of requests received for the DRAM bank during the particular time period. The number of requests is represented as “hits [b]” for a DRAM bank having bank identifier “b” in FIG. 1A. The adaptive precharge scheduler 120 can monitor the number of requests for each DRAM bank and determine the number of requests for each bank pair over the particular time period by determining a sum of the number for each DRAM bank of the bank pair.

Using the number of requests enables the adaptive precharge scheduler 120 to distinguish between a low activity bank pair and a high activity bank pair. For example, the lower the number of requests, the higher the possibility that the adaptive precharge scheduler 120 will select the bank pair for a precharge.

Referring to FIG. 1B, if the number of requests received to access the DRAM cells 158 of bank pair 155-2 is greater than the number of requests to access the DRAM cells of bank pair 155-1, the priority score for bank pair 155-1 may be greater than the priority score for bank pair 155-2, e.g., if all other parameters for the bank pairs 155-1 and 155-2 are equal.

Another parameter that can be used to determine a priority score for a bank pair is the number of priority requests that have been received by the memory controller 110 for the DRAM banks of the bank pair. A priority request can be a request identified as being a priority request by the processor or a request having a corresponding priority level that satisfies a threshold. For example, if a numerical range is used, a priority request may be a request having a priority level of at least five if the range if from zero to ten with ten being the highest level. The number of priority requests received over a time period is a traffic condition parameter that indicates the level of high priority activity of the DRAM bank. The adaptive precharge scheduler 120 can monitor the requests received by the transaction buffer 116 to determine the number of priority requests received to access the bank pair, e.g., over a particular time period. The adaptive precharge scheduler 120 can determine the number of priority requests for a DRAM bank by maintaining a count of the number of priority requests received for the DRAM bank during the particular time period. The number of priority requests is represented as “priority_hits [b]” for a DRAM bank having bank identifier “b” in FIG. 1A. The adaptive precharge scheduler 120 can monitor the number of requests for each DRAM bank and determine the number of requests for each bank pair over the particular time period by determining a sum of the number for each DRAM bank of the bank pair.

Another parameter that can be used to determine a priority score for a bank pair is the number of conflicts detected by the adaptive precharge scheduler 120 for the DRAM banks of the bank pair. The number of conflicts represents a number of requests to access the DRAM banks of the bank pair that conflict with one another, e.g., that are received over a particular time period. An example conflict is two requests that are requesting access to two different rows of the same DRAM bank, e.g., at the same time or within a short period of time such that the row for the first arriving request would still be open when the later request is received. In some DRAM systems, only one row of a DRAM bank can be open at a time. In this example, if the two requests are requesting two different rows of the same DRAM bank to be open at the same time, there is a conflict and only one of the two requests can be processed at a time. For example, referring to FIG. 1B, if a first request is to access data stored in row 157-4 of bank pair 155-1 and a second request is to access data stored in row 157-8 of bank pair 155-1, these two requests would be considered conflicting requests.

The adaptive precharge scheduler 120 can detect conflicts by determining which row of each DRAM bank each request is requesting access and comparing the rows to other requests. If two requests are requesting access to different rows of the same DRAM bank, e.g., within a given time period, the adaptive precharge scheduler 120 can determine that there is a conflict for the DRAM bank. In another example, if a request is received to access a row of a DRAM bank for which a different row is open when the request is received, the adaptive precharge scheduler 120) can determine that there is a conflict for the DRAM bank.

The adaptive precharge scheduler 120 can also determine a number of conflicts and/or a number of priority conflicts detected for each bank pair, e.g., over a particular time period. The number of conflicts for a bank pair over a time period and the number of priority conflicts over a time period are traffic condition parameters. The adaptive precharge scheduler 120 can determine the number of conflicts for a DRAM bank by maintaining a count of the number of conflicts detected by the adaptive precharge scheduler 120 for the DRAM bank over the particular time period. Similarly, the adaptive precharge scheduler 120 can determine the number of priority conflicts for a DRAM bank by maintaining a count of the number of conflicts that include at least one priority request in the conflicting requests detected by the adaptive precharge scheduler 120 for the DRAM bank over the particular time period. The number of conflicts is represented as “conflicts [b]” for DRAM bank “b” in FIG. 1A and the number of priority conflicts is represented as priority_conflicts [b]” for DRAM bank “b” in FIG. 1A. The adaptive precharge scheduler 120 can determine the number of conflicts for a bank pair by determining a sum of the number for conflicts for each DRAM bank in the bank pair. Similarly, the adaptive precharge scheduler 120 can determine the number of priority conflicts for a bank pair by determining a sum of the number for priority conflicts for each DRAM bank in the bank pair.

The number of conflicts can play an important part in determining which bank pair to precharge. For example, among a group of bank pairs for which few or no requests are being received, the bank pair having the highest number of conflicts can be selected for a precharge.

The particular time periods for the various parameters can be the same or different. For example the time periods for counting the number of request parameters can be the same or different from the time periods for counting the number of conflicts parameters.

An example status parameter that can be used to determine the priority score for a bank pair is whether one of the DRAM banks of the bank pair is open. As described above, this status information can be obtained from the bank status module 114. At any point in time, a bank pair can be in three configurations, i.e., both banks open, both banks closed, or only one bank open. A bank can be considered open if any row of the bank is open. In general, the adaptive precharge scheduler 120 would not, or may not be able to, send a precharge command to closed banks since the banks are already closed. Among the other two cases, both banks being open can involve two PRE commands to be issued while only one PRE command would be involved if one bank is open. As two PRE commands can take more time than one PRE command, issuing the PRE command to a bank pair with one open bank can take less time than issuing PRE commands to a bank pair with two banks open. Selecting the bank pair with one bank open can therefore reduce the latency in issuing the refresh command.

Another status parameter that can be used to determine the priority score for a bank pair is the refresh status for each DRAM bank of the bank pair. The refresh status can indicate whether the DRAM bank is in a prepone stage, a postpone stage, or is close to the refresh deadline for the DRAM bank, e.g., within a threshold amount of time of being required to be refreshed per the applicable DRAM standards. The refresh scheduler 118 can provide, to the adaptive precharge scheduler 120, data indicating the refresh status of each DRAM bank, e.g., over a custom interface between the refresh scheduler 118 and the adaptive precharge scheduler 120.

The scoring module 122 can determine the priority score for each bank pair based on one or more of the traffic condition parameters and/or one or more of the status conditions for the bank pair. The scoring module 122 can use any combination of these parameters to determine the priority score for the bank pair. The scoring module 122 can determine the priority score for a bank pair using a weighted combination of the parameters. In this example, each parameter can be represented as an individual score and each individual score can be weighted based on its relative importance in determining the priority score. The scoring module 122 can determine the weighted score for a parameter by determining a product of the individual score and its corresponding weight. The scoring module 122 can then determine the priority score by aggregating, e.g., averaging, the weighted scores for the parameters. To obtain the individual scores, the scoring module 122 can convert the various parameters for a bank pair to numerical values that represent the parameter, if the parameter is not already expressed using a number.

In some implementations, the priority score for a bank pair is represented by a score vector with each parameter being represented by the vector. The binary value (or converted decimal value) of the score vector can be the priority score or be directly proportional to the priority score. An example 13 bit score vector for a bank pair is shown in Table 1 below:

TABLE 1

| Field | Bits of Score Vector |
|---|---|
| Number of Priority Requests | [12:9] |
| One Bank Open Status | [8] |
| Number of Priority Conflicts | [7:6] |
| Number of Normal (non-priority) Requests | [5:2] |
| Number of Normal (non-priority) Conflicts | [1:0] |

In this example, the higher number bits represent the higher priority parameters for the priority score as these bits represent the more significant bits in the priority score represented by the score vector. That is, in this example, the number of priority requests has a greater influence on the priority score than each other parameter in the score vector. The single bit for the one open bank status can have a value of one if one DRAM bank in the bank pair is open and a value of zero if either both banks are open or both banks are closed.

The memory controller 110 can use other arrangements of parameters in a score vector. For example, the score vector can include one or more additional bits to represent whether any DRAM banks in the bank pair is in a prepone stage, a postpone stage, or whether a bank is close to being required to be refreshed. In another example, the parameters can be reordered in the score vector such that other parameters have greater influence on the priority score. For example, the number of conflicts can be represented by bits 12 and 11 if it is the highest priority parameter. The arrangement of parameters and the parameters included in the score vector can vary based on the implementation or use case.

The scoring module 122 can continuously or periodically determine the priority scores for the bank pairs and provide the priority scores to the PRE request generator 124. The priority score for a bank is represented as “Score [b]” in FIG. 1.

The PRE request generator 124 includes a scheduling module 126 that can select a next bank pair to send a PRE command based on the priority scores. For example, the scheduling module 126 can determine a schedule of bank pairs to precharge based on the priority scores for the bank pairs. The schedule can be ordered from highest priority score to lowest priority score. For example, the PRE request generator 124 can issue a PRE command to each DRAM bank of the bank pair having the highest priority score.

As described above, a PRE command closes the rows of the DRAM banks. The refresh scheduler 112 can then send a refresh command, e.g., a REFpb command, to the closed DRAM bank pairs to refresh the DRAM bank pairs.

In some implementations, the adaptive precharge scheduler 120 can select one or more bank pairs to send PRE commands based on one or more of the traffic conditions parameters and/or the status parameters, e.g., without determining scores and/or without ranking or ordering the bank pairs. The adaptive precharge scheduler 120 has access to whether each DRAM bank is open or closed at all times. It can be advantageous to select an already closed DRAM bank if all other parameters are equal. Thus, the PRE request generator 124 can send a PRE command to close a single DRAM bank of a bank pair that already has one DRAM bank closed preemptively considering traffic conditions to that bank pair to aid in issuing refreshes to that bank pair.

It can also be advantageous to avoid sending refresh commands to DRAM banks that have priority transactions. The adaptive precharge scheduler 120 can use the number of priority requests to avoid precharging bank pairs that have priority requests and instead select a different bank pair. The adaptive precharge scheduler 120 can instruct the refresh scheduler 112 to refresh the different bank pair.

The adaptive precharge scheduler 120 can also ensure that an activate command does not go through to a DRAM bank during the time period in which the adaptive precharge scheduler 120 has selectively precharged a bank or bank pair and made it ready to issue a refresh the bank pair. For example, the adaptive precharge scheduler 120 can instruct the request scheduler 118 to not send activate commands to the DRAM bank during the time period or until the adaptive precharge scheduler 120 indicates that the refresh is completed for the DRAM bank, e.g., over a communication interface between the adaptive precharge scheduler 120 and the request scheduler 118. In another example, the adaptive precharge scheduler 120 can block activate commands from reach the DRAM bank, e.g., by communication with logic (not shown) that is downstream from the request scheduler 118 until the refresh is complete.

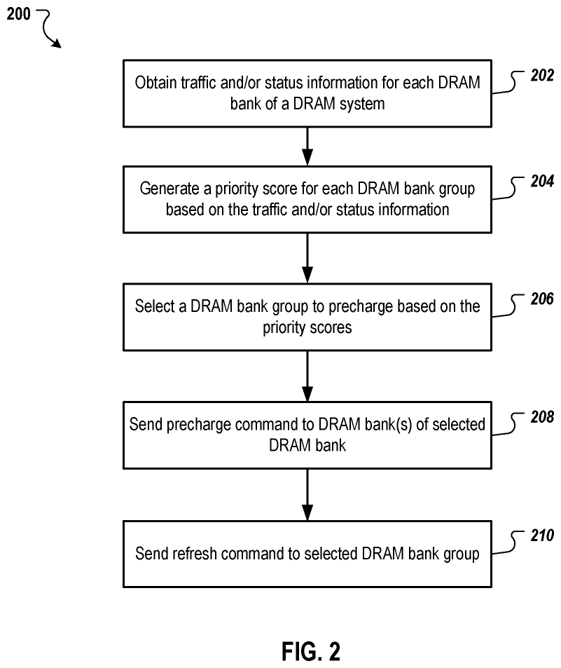

FIG. 2 is a flow diagram of an example process 200 for refreshing DRAM cells. The process 200 can be performed by a memory controller of a DRAM system, e.g., the memory controller 110 of FIG. 1A. The DRAM can include DRAM banks arranged in DRAM bank groups that each include one or more DRAM banks. For example, each DRAM bank group can be a bank pair, as described above.

An adaptive precharge scheduler, e.g., the adaptive precharge scheduler 120 of FIG. 1, obtains traffic and/or status information for each DRAM bank of the DRAM system (202). This information can include a set of parameters. The set of parameters can include, for example, one or more status parameters that indicate a status of the one or more DRAM banks and/or one or more traffic condition parameters that indicate a characteristic of data traffic for the one or more DRAM bank.

As described above, a status parameter can indicate the number of DRAM banks open in the DRAM bank group. The traffic condition parameters can include a number of requests received for the DRAM bank group, the number of priority requests received for the DRAM bank group, the number of conflicts detected for the DRAM bank group, and/or the number of priority conflicts detected for the DRAM bank group. These traffic condition parameters can be determined for a particular time period, e.g., over the previous second, the previous 10 seconds, the previous minute, or another appropriate time period.

The adaptive precharge scheduler determines a priority score for each DRAM bank (204). The adaptive precharge scheduler can determine the priority score for a DRAM bank based on the set of parameters for the DRAM bank. As described above, in some implementations, the adaptive precharge scheduler generates a score vector that represents the priority score for the DRAM bank group. In another example, the adaptive precharge scheduler can determine, as the priority score for a bank group, a weighted combination of the parameters, e.g., a weighted average of the parameters.

The adaptive precharge scheduler selects a DRAM bank group (206). The adaptive precharge scheduler can select a DRAM bank group to close so that the DRAM bank(s) of the DRAM bank group can be refreshed by a refresh scheduler, e.g., the refresh scheduler 112 of FIG. 1A. The adaptive precharge scheduler can select the DRAM bank group based on the priority scores for the DRAM bank groups. For example, the adaptive precharge scheduler can select the DRAM bank group that has the highest priority score.

The adaptive precharge scheduler sends a precharge command to at least one DRAM bank of the selected DRAM bank group (208). The adaptive precharge scheduler can send the precharge command to each DRAM bank, or each row, that is open in the selected DRAM bank group. For example, if only one DRAM bank of a selected DRAM bank group that has multiple DRAM banks is open, the adaptive precharge scheduler may only send a precharge command to the open DRAM bank. In another example, if a proper subset of the rows of a DRAM bank of the DRAM bank group is open, the adaptive precharge scheduler can send a precharge command to each row in the proper subset, e.g., without sending a precharge command to any closed rows of the DRAM bank group.

The adaptive precharge scheduler or the refresh scheduler sends a refresh command to the selected DRAM bank group (210). The refresh command can be send to each DRAM bank in the DRAM bank group. For example, the refresh scheduler can detect that the DRAM bank(s) of the DRAM bank group are closed and issue a refresh command to the DRAM bank(s) in response to detecting that they are closed. In another example, the adaptive precharge scheduler can notify the refresh scheduler that the DRAM bank pair is ready for a refresh and, in response to receiving the notification, the refresh scheduler can issue the refresh command to the DRAM bank(s).

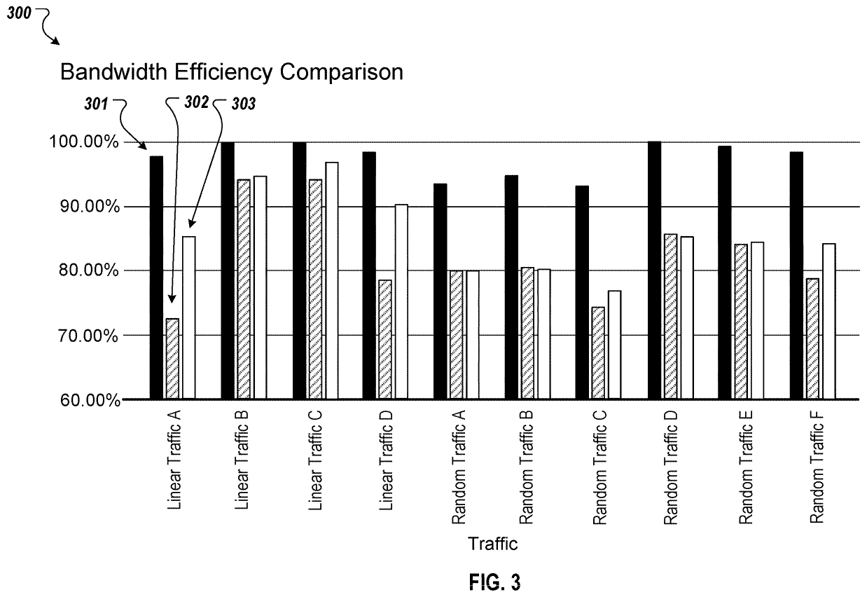

FIG. 3 is a graph 300 that shows bandwidth efficiency improvements of using a traffic aware adaptive precharge scheduler. The graph 300 shows the relative bandwidth efficiency of a DRAM system for various types of traffic when refresh is disabled, when refresh is enabled without adaptive precharge scheduling, and when refresh is enabled with adaptive precharge scheduling. In particular, the left bar 301 for each type of traffic represents the bandwidth efficiency when refresh is disabled, the middle bar 302 for each type of traffic represents the bandwidth efficiency when refresh is enabled without adaptive precharge scheduling, and the right bar 303 for each type of traffic represents the bandwidth efficiency when refresh is enabled with adaptive precharge scheduling.

As shown in this graph 300, when refresh is disabled and the memory cells do not ever need to be refreshed, the bandwidth is highest as there are no blackout periods where memory cells are inaccessible. However, this is not possible for DRAM memory systems or other memory systems that would require refreshes. Using adaptive precharge scheduling as described above provides bandwidth efficiency improvements when refresh is required relative to not using adaptive precharge scheduling for most types of traffic shown represented by the graph 300.

Bandwidth efficiency is an important metric in determining the performance of a memory controller. The bandwidth efficiency can be determined by dividing the total bandwidth by the peak bandwidth. The total bandwidth can be the sum of the read bandwidth and write bandwidth. The read bandwidth can be determined as the product of the number of read transactions and the size of the data of the transactions divided by the total time taken to process the transactions. Similarly, the write bandwidth can be determined as the product of the number of write transactions and the size of the data of the transactions divided by the total time taken to process the transactions. Peak bandwidth refers to the maximum bandwidth that can be achieved in a particular mode of operation of a given memory type.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non transitory program carrier for execution by, or to control the operation of, data processing apparatus. Alternatively or in addition, the program instructions can be encoded on an artificially generated propagated signal, e.g., a machine-generated electrical, optical, or electromagnetic signal, that is generated to encode information for transmission to suitable receiver apparatus for execution by a data processing apparatus. The computer storage medium can be a machine-readable storage device, a machine-readable storage substrate, a random or serial access memory device, or a combination of one or more of them.

The processes and logic flows described in this specification can be performed by one or more programmable computers executing one or more computer programs to perform functions by operating on input data and generating output. The processes and logic flows can also be performed by, and apparatus can also be implemented as, special purpose logic circuitry, e.g., an FPGA (field programmable gate array), an ASIC (application specific integrated circuit), or a GPGPU (General purpose graphics processing unit).

Computers suitable for the execution of a computer program include, by way of example, can be based on general or special purpose microprocessors or both, or any other kind of central processing unit. Generally, a central processing unit will receive instructions and data from a read only memory or a random access memory or both. The essential elements of a computer are a central processing unit for performing or executing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer readable media suitable for storing computer program instructions and data include all forms of non volatile memory, media and memory devices, including by way of example semiconductor memory devices, e.g., EPROM, EEPROM, and flash memory devices: magnetic disks, e.g., internal hard disks or removable disks: magneto optical disks; and CD ROM and DVD-ROM disks. The processor and the memory can be supplemented by, or incorporated in, special purpose logic circuitry.

While this specification contains many specific implementation details, these should not be construed as limitations on the scope of any invention or of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous.

1. A memory controller, comprising:
a refresh scheduler configured to send refresh commands to dynamic random-access memory (DRAM) banks of a DRAM memory system comprising DRAM banks arranged in a set of DRAM bank groups each comprising one or more DRAM banks; and
an adaptive precharge scheduler configured to:
determine a priority score for each DRAM bank group based on a set of parameters comprising at least one of (i) one or more status parameters that indicate a status of the one or more DRAM banks or (ii) one or more traffic condition parameters that indicate a characteristic of data traffic for the one or more DRAM bank;
select, based on the priority score for each DRAM bank group, a particular DRAM bank group to close so that each DRAM bank in the DRAM bank group can be refreshed by the refresh scheduler; and
send the precharge command to at least one DRAM bank of the particular DRAM group.

2. The memory controller of claim 1, wherein the refresh scheduler is configured to detect that the at least one DRAM bank is closed and send a refresh command to the at least one DRAM bank in response to detecting that the at least one DRAM bank is closed.

3. The memory controller of claim 2, wherein detecting that the at least one DRAM bank is closed comprises receiving, from the adaptive precharge scheduler, data indicating that the at least one DRAM bank is closed.

4. The memory controller of claim 1, wherein the one or more status parameters for each DRAM bank group comprise a parameter indicating a number of DRAM banks of the DRAM bank group that are open.

5. The memory controller of claim 1, wherein the one or more traffic condition parameters for each DRAM bank group comprise a number of memory requests received for the DRAM bank group.

6. The memory controller of claim 1, wherein the one or more traffic condition parameters for each DRAM bank group comprise a number of priority memory requests received for the DRAM bank group.

7. The memory controller of claim 1, wherein the one or more traffic condition parameters for each DRAM bank group comprise a number of memory request conflicts detected for the DRAM bank group.

8. The memory controller of claim 1, wherein the one or more traffic condition parameters for each DRAM bank group comprise a number of priority memory request conflicts detected for the DRAM bank group.

9. The memory controller of claim 1, wherein the priority score for each DRAM bank group is represented by a score vector that orders the set of parameters within the score vector based on a relative importance of each parameter.

10. The memory controller of claim 1, wherein the one or more status parameters for each DRAM bank group comprise a refresh status indicating whether the DRAM bank is in a prepone stage, a postpone stage, or is close to a refresh deadline for the DRAM bank.

11. A method, comprising:
sending, by a refresh scheduler of a memory controller, refresh commands to dynamic random-access memory (DRAM) banks of a DRAM memory system comprising DRAM banks arranged in a set of DRAM bank groups each comprising one or more DRAM banks;
determining, by an adaptive precharge scheduler of the memory controller, a priority score for each DRAM bank group based on a set of parameters comprising at least one of (i) one or more status parameters that indicate a status of the one or more DRAM banks or (ii) one or more traffic condition parameters that indicate a characteristic of data traffic for the one or more DRAM bank;
selecting, by the adaptive precharge scheduler and based on the priority score for each DRAM bank group, a particular DRAM bank group to close so that each DRAM bank in the DRAM bank group can be refreshed by the refresh scheduler; and
sending, by the adaptive precharge scheduler, the precharge command to at least one DRAM bank of the particular DRAM group.

12. The method of claim 11, further comprising, detecting, by the refresh scheduler, that the at least one DRAM bank is closed and sending a refresh command to the at least one DRAM bank in response to detecting that the at least one DRAM bank is closed.

13. The method of claim 12, wherein detecting that the at least one DRAM bank is closed comprises receiving, from the adaptive precharge scheduler, data indicating that the at least one DRAM bank is closed.

14. The method of claim 11, wherein the one or more status parameters for each DRAM bank group comprise a parameter indicating a number of DRAM banks of the DRAM bank group that are open.

15. The method of claim 11, wherein the one or more traffic condition parameters for each DRAM bank group comprise a number of memory requests received for the DRAM bank group.

16. The method of claim 11, wherein the one or more traffic condition parameters for each DRAM bank group comprise a number of priority memory requests received for the DRAM bank group.

17. The method of claim 11, wherein the one or more traffic condition parameters for each DRAM bank group comprise a number of memory request conflicts detected for the DRAM bank group.

18. The method of claim 11, wherein the one or more traffic condition parameters for each DRAM bank group comprise a number of priority memory request conflicts detected for the DRAM bank group.

19. The method of claim 11, wherein the priority score for each DRAM bank group is represented by a score vector that orders the set of parameters within the score vector based on a relative importance of each parameter.

20. The method of claim 11, wherein the one or more status parameters for each DRAM bank group comprise a refresh status indicating whether the DRAM bank is in a prepone stage, a postpone stage, or is close to a refresh deadline for the DRAM bank
